(19) United States
(12) Patent Application Publication
(10) Pub. No.: US 2003/0062592 A1
(43) Pub. Date: Apr. 3, 2003

(54) Fuse element, semiconductor device and method for manufacturing the same

(76) Inventors: Hisakatsu Sato, Sakata-shi (JP); Hiro Sato, Sakata-shi (JP); Masashi Miura, Sakata-shi (JP); Yuriko Watanabe, Sakata-shi (JP); Kenji Yokoyama, Sakata-shi (JP)

Correspondence Address: HARNESS, DICKEY & PIERCE, P.L.C., P.O. BOX 828, BLOOMFIELD HILLS, MI, 48303, US

(21) Appl. No.: 10/229,315

(22) Filed: Aug. 27, 2002

(30) Foreign Application Priority Data
Aug. 27, 2001 (JP) 2001-255995

(51) Int. Cl. H01L 29/00

(52) U.S. Cl. 257/529

(57) ABSTRACT

A semiconductor device in accordance with the present invention is equipped with a fuse element 13 that is formed on an interlayer dielectric film 14 and formed in the same layer as an Al alloy wiring in the uppermost layer, a silicon oxide film 16 formed over the fuse element 13 and the interlayer dielectric film 14, a silicon nitride film 17 formed on the silicon oxide film 16, and an window for fusing 17a formed in the silicon nitride film 17 and located above the fuse element 13.

### BACKGROUND OF THE INVENTION

1. Technical Field of the Invention

The present invention relates to fuse elements, semiconductor devices and methods for manufacturing the same, and more particularly, to reducing failures in cutting fuse elements.

2. Background Technology

Semiconductor devices, such as, for example, semiconductor memory devices may be equipped with redundant circuits. When a memory cell array has a defect, the defect is replaced with a redundant circuit. For replacement with the redundant circuit, a current may be applied to a fuse element for cutting the same, or a laser beam may be irradiated on a fuse element for cutting the same.

FIGS. 10-12 show in cross section a conventional method for manufacturing a semiconductor device.

First, as shown in FIG. 10(a), a silicon oxide film 112 as a base film is formed above a semiconductor substrate by a CVD (Chemical Vapor Deposition) method. Then, an Al alloy film is deposited on the silicon oxide film 112 by sputtering. By patterning the Al alloy film, a fuse element 113 is formed as a redundant wiring. In this instance, Al alloy wirings (not shown) are formed in addition to the fuse element 113. The Al alloy wirings are in a wiring layer that is located one layer below the uppermost wiring layer.

Next, as shown in FIG. 10(b), an interlayer dielectric film 114 composed of a silicon oxide film is deposited on the entire surface including the fuse element 113 by a CVD method.

Next, as shown in FIG. 10(c), an Al alloy film is deposited on the interlayer dielectric film 114 by sputtering. Through patterning the Al alloy film, a pad 115 is formed on the interlayer dielectric film. In this instance, Al alloy wirings (not shown) are formed in addition to the pad 115. The Al alloy wirings are in the uppermost wiring layer.

Then, as shown in FIG. 11(d), a passivation film 116 composed of a silicon nitride film is deposited on the entire surface including the pad 115.

Next, as shown in FIG. 11(e), a photoresist film is coated on the passivation film 116, and the photoresist film is exposed and developed to form a resist pattern 117 on the passivation film.

Next, as shown in FIG. 12(f), the passivation film 116 and the interlayer dielectric film 114 are etched using the resist pattern 117 as a mask. As a result, an opening section 116a located above the pad 115 is formed in the passivation film 116, and an open window 116b located above the fuse element 113 is formed in the passivation film 116 and the interlayer dielectric film 114. The open window 116b is deeper than the opening section 116a because an over-etching is conducted to completely expose the upper portion of the pad 115 in the opening section 116a.

Next, a metal bump (not shown) is formed inside and over the opening section 116a on the pad 115 by a plating method. Then, an examination step is conducted, and the fuse element 113 may be cut if necessary. As a cutting method, a specified voltage is applied on both ends of the fuse element 113, to flow a specified current between both ends of the fuse element 113 to cut the fuse element. Also, another cutting method involves irradiating a laser beam on the fuse element 113 to cut the same.

It is noted that a film of the interlayer dielectric film 114 remaining on the fuse element is adjusted to a specified thickness, because the fuse may not be cut if the thickness is too large. In other words, as the miniaturization of semiconductor elements advances, transistor voltages are lowered in order to reduce power consumption, but the film thickness of interlayer dielectric films over fuses has increased due to multiple wiring layer structures. Since the applied voltage or laser energy required for cutting fuses needs to be lowered, the fuses cannot be cut if the film thickness of the interlayer dielectric film over the fuses is large.

However, when the open window 116b is formed by etching the interlayer dielectric film having a great thickness, it is difficult to control the film thickness of the film remaining on the fuse element, and the film thickness may become greater than a target film thickness of the film that is to remain on the fuse element. In particular, since the advanced miniaturization of semiconductor elements requires planarization of interlayer dielectric films, a SOG film, for example, may be used as the interlayer dielectric film 114. However, the amount of standing material of SOG film may vary, and thus the control of film thickness is difficult. In other words, the amount of standing SOG material on fuses may substantially vary due to LOCOS oxide films, polysilicon wirings and Al alloy wirings, and thus the film thickness remaining on the fuses has variations. In this case, the control of film thickness of the film that remains on the fuses is particularly difficult. When the film thickness of the remaining film on the fuses is large, the fuse elements cannot be cut, which results in defective products.

Furthermore, in the conventional method for manufacturing semiconductor devices described above, an over-etching is conducted to form the window for fusing 116b that is deeper than the opening section 116a over the pad 115. This may roughen the surface of the pad 115.

The present invention has been made in view of the problems described above, and one object is to provide fuse elements, semiconductor devices and a method for manufacturing the same, which can reduce failures in cutting fuse elements.

### SUMMARY OF THE INVENTION

To solve the problems described above, a fuse element in accordance with the present invention pertains to a fuse element formed on a dielectric film, characterized in that the fuse element and an uppermost wiring layer are formed in the same layer.

Also, in the fuse element in accordance with the present invention, the fuse element and pads for external connection may preferably be formed in the same layer.

Also, in the fuse element in accordance with the present invention, the wiring layer may preferably be a wiring layer composed of an Al alloy film.

A semiconductor device in accordance with the present invention is characterized in comprising:

a fuse element formed on a dielectric film, the fuse element and an uppermost wiring layer being formed in the same layer;

a first passivation film formed on the fuse element and the dielectric film;

a second passivation film formed on the first passivation film; and

a window for fusing formed in the second passivation film, and located above the fuse element.

A semiconductor device in accordance with the present invention is characterized in comprising:

a pad formed in a dielectric film;

a fuse element formed on the dielectric film, the fuse element and the pad being formed in the same layer;

a first passivation film formed on the fuse element, the pad and the dielectric film;

a second passivation film formed on the first passivation film;

a window for fusing formed in the second passivation film, and located above the fuse element; and

an opening section formed in the first passivation film and the second passivation film, and located above the pad.

A semiconductor device in accordance with the present invention is characterized in comprising:

a fuse element formed on a dielectric film, the fuse element and an uppermost wiring layer being formed in the same layer;

a passivation film formed on the fuse element and the dielectric film; and

a window for fusing formed in the passivation film, and located above the fuse element, wherein a part of the passivation film remains between the fuse element and the window for fusing.

A semiconductor device in accordance with the present invention is characterized in comprising:

a pad formed on a dielectric film;

a fuse element formed on the dielectric film, the fuse element and the pad being formed in the same layer;

a passivation film formed on the pad and the dielectric film;

a window for fusing formed in the passivation film, and located above the fuse element; and

an opening section formed in the passivation film, and located above the pad, wherein a part of the passivation film remains between the fuse element and the window for fusing, and the pad is exposed through the opening section.

The semiconductor device in accordance with the present invention may further include a first wiring formed below the dielectric film and connected to one end of the fuse element, and a second wiring formed below the dielectric film and connected to another end of the fuse element.

A method for manufacturing a semiconductor device in accordance with the present invention is characterized in comprising the steps of:

depositing a metal film on a dielectric film, and pattering the metal film to form a fuse element on the dielectric film;

forming a first passivation film on the fuse element and the dielectric film;

forming a second passivation film on the first passivation film; and

forming a window for fusing located above the fuse element in the second passivation film, wherein the fuse element and an uppermost wiring layer are formed in the same layer.

In the method for manufacturing a semiconductor device in accordance with the present invention, the fuse element and the upper most wiring layer are formed in the same layer. Therefore, a film of the interlayer dielectric film that is to remain on the fuse element does not have to be controlled by etching as with a conventional semiconductor device, and the thickness of the interlayer dielectric film over the fuse element can be controlled with the film thickness of the first passivation film. Accordingly, the film thickness of the interlayer dielectric film over the fuse element can be readily controlled. As a result, cutting failures in the fuse cutting step can be reduced.

A method for manufacturing a semiconductor device in accordance with the present invention is characterized in comprising the steps of:

depositing a metal film on a dielectric film, and pattering the metal film to form a fuse element and a pad on the dielectric film;

forming a first passivation film on the fuse element, the pad and the dielectric film;

forming a second passivation film on the first passivation film;

etching the first passivation film and the second passivation film to form an opening section located above the pad in the first passivation film and the second passivation film; and

etching the second passivation film to form a window for fusing located above the fuse element in the second passivation film.

In the method for manufacturing a semiconductor device in accordance with the present invention, the fuse element and the pad in the upper most layer are formed in the same layer. Therefore, a film of the interlayer dielectric film that is to remain on the fuse element does not have to be controlled by etching as with a conventional semiconductor device, and the thickness of the interlayer dielectric film over the fuse element can be controlled with the film thickness of the first passivation film. Accordingly, the film thickness of the interlayer dielectric film over the fuse element can be readily controlled. As a result, cutting failures in the fuse cutting step can be reduced.

A method for manufacturing a semiconductor device in accordance with the present invention is characterized in comprising the steps of:

depositing a metal film on a dielectric film, and pattering the metal film to form a fuse element and a pad on the dielectric film;

forming a first passivation film on the fuse element, the pad and the dielectric film;

forming a second passivation film on the first passivation film;

etching the first passivation film to form a window for fusing located above the fuse element in the first passivation film, and forming a first opening section located above the pad in the first passivation film; and

etching the second passivation film to form a second opening section located above the pad in the second passivation film,

wherein the first opening section is connected to the second opening section.

A method for manufacturing a semiconductor device in accordance with the present invention is characterized in comprising the steps of:

depositing a metal film on a dielectric film, and pattering the metal film to form a fuse element on the dielectric film;

forming a passivation film on the fuse element and the dielectric film; and

forming a window for fusing located above the fuse element in the passivation film,

wherein the fuse element and an uppermost wiring layer are formed in the same layer, and a part of the passivation film remains between the fuse element and the window for fusing.

In the method for manufacturing a semiconductor device in accordance with the present invention, the fuse element and the upper most wiring layer are formed in the same layer. Therefore, a remaining film of the interlayer dielectric film over the fuse element can be more readily controlled compared to a conventional semiconductor device. As a result, cutting failures in the fuse cutting step can be reduced.

A method for manufacturing a semiconductor device in accordance with the present invention is characterized in comprising the steps of:

depositing a metal film on a dielectric film, and pattering the metal film to form a fuse element and a pad on the dielectric film;

forming a passivation film on the fuse element, the pad and the dielectric film; and

etching the passivation film to form an opening section located above the pad in the passivation film; and

etching the passivation film to form a window for fusing located above the fuse element,

wherein a part of the passivation film remains between the fuse element and the window for fusing.

In the method for manufacturing a semiconductor device in accordance with the present invention, the fuse element and the pad in the upper most layer are formed in the same layer. Therefore, a remaining film of the interlayer dielectric film over the fuse element can be more readily controlled compared to a conventional semiconductor device. As a result, cutting failures in the fuse cutting step can be reduced.

Also, the method for manufacturing a semiconductor device in accordance with the present invention can further include the step of cutting the fuse element after the step of forming the window for fusing.

A method for manufacturing a semiconductor device in accordance with the present invention is characterized in comprising the steps of:

depositing a metal film on a dielectric film, and pattering the metal film to form a fuse element and a pad on the dielectric film;

forming a passivation film on the fuse element, the pad and the dielectric film;

etching the passivation film to form a window for fusing located above the fuse element in the passivation film, and forming a first opening section located above the pad in the passivation film; and

etching the passivation film to form a second opening section located above the pad,

wherein a part of the passivation film remains between the fuse element and the window for fusing, and the first opening section is connected to the second opening section.

The method for manufacturing a semiconductor device in accordance with the present invention may further include the step of cutting the fuse element after the step of forming the second opening section.

### BRIEF DESCRIPTION OF THE DRAWINGS

FIG. 1(a) is a plan view of a semiconductor device equipped with a fuse element in accordance with a first embodiment of the present invention. FIG. 1(b) is a cross-sectional view taken along line 1b-1b indicated in FIG. 1(a), and FIG. 1(c) is a cross-sectional view taken along line 1c-1c indicated in FIG. 1(a).

FIGS. 2(a)-(c) show in cross section a method for manufacturing a semiconductor device equipped with the fuse element shown in FIG. 1.

FIGS. 3(d) and 3(e) show in cross section a method for manufacturing a semiconductor device equipped with the fuse element shown in FIG. 1.

FIGS. 4(a)-(c) show in cross section a method for manufacturing a semiconductor device equipped with a fuse element in accordance with a second embodiment of the present invention.

FIGS. 5(d) and 5(e) show in cross section the method for manufacturing a semiconductor device equipped with a fuse element in accordance with the second embodiment of the present invention, and shows cross sections in steps after FIG. 4(c).

FIGS. 6(a)-(c) show in cross section a method for manufacturing a semiconductor device equipped with a fuse element in accordance with a third embodiment of the present invention.

FIGS. 7(d) and 7(e) show in cross section the method for manufacturing a semiconductor device equipped with a fuse element in accordance with the third embodiment of the present invention, and shows cross sections in steps after FIG. 6(c).

FIGS. 8(a)-(c) show in cross section a method for manufacturing a semiconductor device equipped with a fuse element in accordance with a fourth embodiment of the present invention.

FIGS. 9(d) and 9(e) show in cross section the method for manufacturing a semiconductor device equipped with a fuse element in accordance with the fourth embodiment of the present invention, and shows cross sections in steps after FIG. 8(c).

FIGS. 10(a)-10(c) show cross sections for describing a conventional method for manufacturing a semiconductor device.

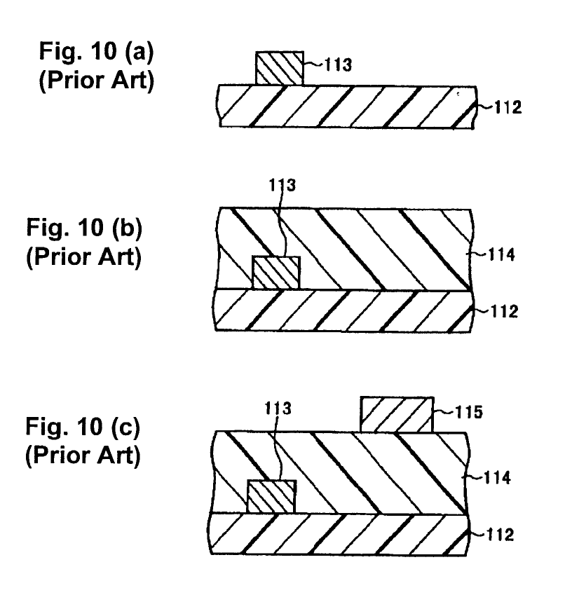

FIGS. 11(d) and 11(e) show in cross section the conventional method for manufacturing a semiconductor device, and shows cross sections in steps after FIG. 10(c).

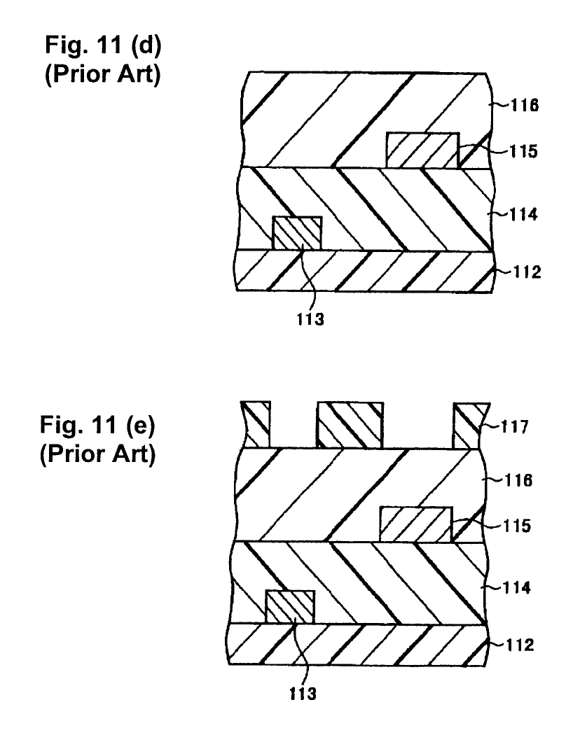

FIGS. 12(f) and 12(g) show in cross section the conventional method for manufacturing a semiconductor device, and shows cross sections in steps after FIG. 11(e).

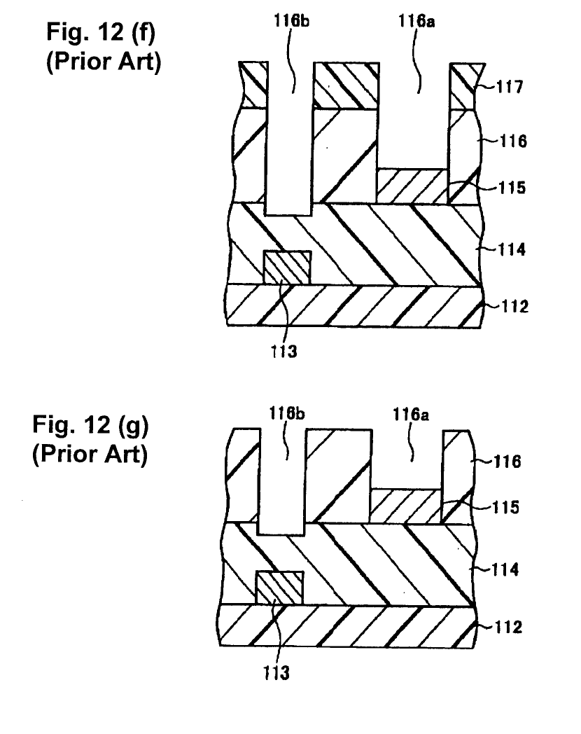

### DETAILED DESCRIPTION OF THE PREFERRED EMBODIMENTS OF THE PRESENT INVENTION

Embodiments of the present invention will be described below with reference to the accompanying drawings.

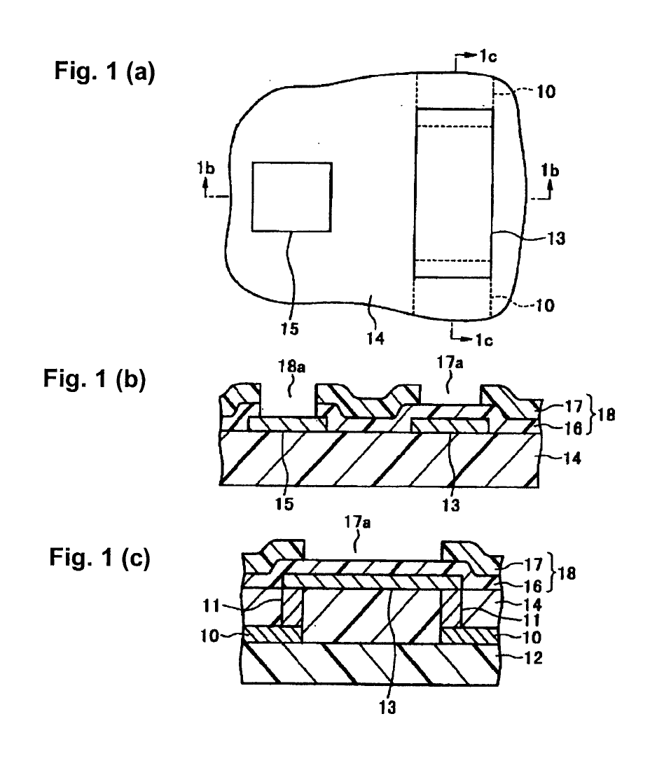

FIG. 1(a) is a plan view of a semiconductor device equipped with a fuse element in accordance with a first embodiment of the present invention. FIG. 1(b) is a cross-sectional view taken along line 1b-1b indicated in FIG. 1(a), and FIG. 1(c) is a cross-sectional view taken along line 1c-1c indicated in FIG. 1(a).

The semiconductor device shown in FIG. 1(a) includes a fuse element 13 and a pad 15 composed of Al alloy films that are present in the same layer(i.e., level) as AL alloy wirings in the uppermost layer. As shown in FIG. 1(b), an interlayer dielectric film 14 composed of a silicon oxide film or the like is formed below the fuse element 13 and the pad 15. A passivation film 18 is formed on the interlayer dielectric film 14, the fuse element 13 and the pad 15. The passivation film 18 is formed from a silicon nitride film 17 as an upper film and a silicon oxide film 16 as a lower film. A window for fusing 17a located above the fuse element 13 is formed in the silicon nitride film 17. An opening section 18a located above the pad 15 is formed in the passivation film 18 (i.e., through the silicon nitride film 17 and the silicon oxide film 16). A metal bump (not shown) is formed within and over the opening section 18a depending on the requirements.

As shown in FIG. 1(c), connection holes located below both ends of the fuse element 13 are formed in the interlayer dielectric film 14, and W plugs 11, for example, are embedded in the connection holes. Al alloy wirings 10 are formed below the W plugs 11 and the interlayer dielectric film 14. The Al alloy wirings 10 are wiring layers located one layer below the uppermost wiring layer. The Al alloy wirings 10 are connected to both ends of the fuse element 13 through the W plugs 11. A dielectric film 12 such as a silicon oxide film is formed below the Al alloy wirings 10 and the interlayer dielectric film 14.

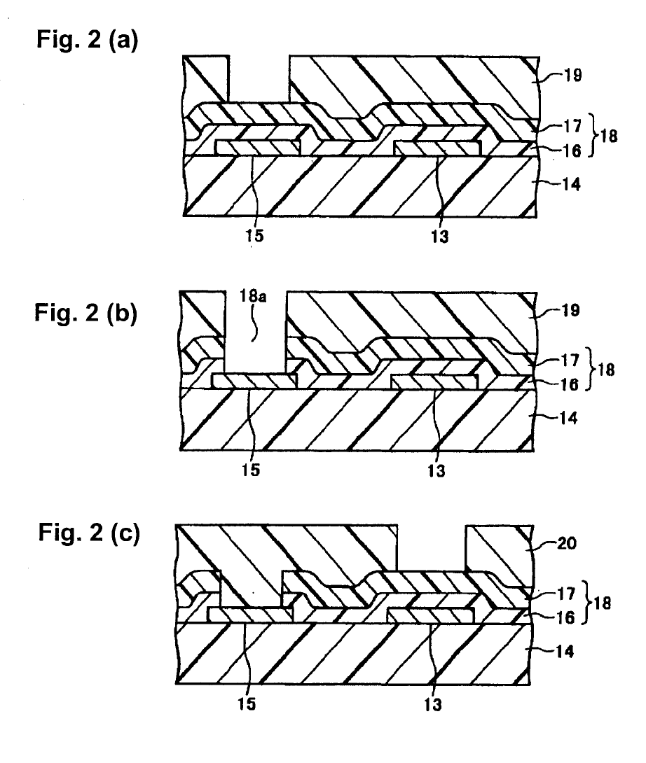

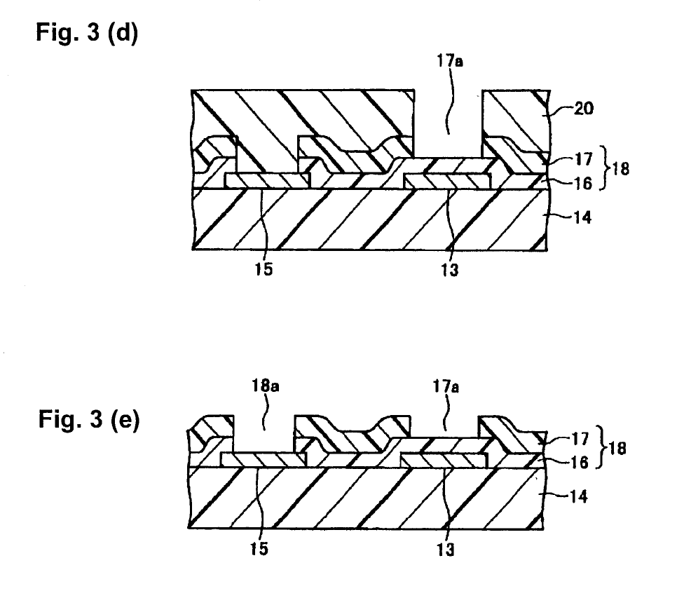

FIGS. 2(a)-(c) and FIGS. 3(d) and 3(e) show in cross section a method for manufacturing a semiconductor device equipped with the fuse element shown in FIG. 1.

First, as shown in FIG. 2(a), a dielectric film composed of a silicon oxide film or the like is formed above a semiconductor substrate, and an interlayer dielectric film 14 composed of a silicon oxide film or the like is deposited on the dielectric film by a CVD method. Then, an Al alloy film is deposited on the interlayer dielectric film 14 by sputtering. The Al alloy film is patterned to form a fuse element 13, a pad 15 and Al alloy wirings (not shown) are formed on the interlayer dielectric film 14. The Al alloy wirings are wiring layers in the uppermost layer, and the fuse element 13 and the pad 15 are also formed from similar wiring layers in the uppermost layer.

Next, a silicon oxide film 16 is deposited by a CVD method on the entire surface including the pad 15 and the fuse element 13. Then, a silicon nitride film 17 is deposited by a CVD method on the silicon oxide film 16. The silicon nitride film 17 and the silicon oxide film 16 act as a passivation film 18. Then, a photoresist film is coated on the passivation film 18, and the photoresist film is exposed and developed to form a resist pattern 19 on the passivation film 18.

Then, as shown in FIG. 2(b), the silicon nitride film 17 and the silicon oxide film 16 are continuously etched using the resist pattern 19 as a mask. As a result, an opening section 18a located above the pad 15 is formed in the passivation film 18, and the surface of the pad 15 is exposed.

Next, as shown in FIG. 2(c), the resist pattern 19 is removed. Then, a photoresist film is coated on the passivation film 18, and the photoresist film is exposed and developed to form a resist pattern 20 on the passivation film 18.

Then, as shown in FIG. 3(d), the silicon nitride film 17 is etched using the resist pattern 20 as a mask, whereby a window for fusing 17a located above the fuse element 13 is formed in the silicon nitride film 17. Next, as shown in FIG. 3(e), the resist pattern 20 is removed.

Next, a metal bump (not shown) is formed within and over the opening section 18a over the pad by a plating method. Then, an examination step is conducted, and the fuse element 13 may be cut depending on the requirements. As a cutting method, a specified voltage is applied to the Al alloy wiring 10 (see FIG. 1(c)), to flow a specified current between both ends of the fuse element 13 to cut the fuse element 13. Also, another cutting method involves irradiating a laser beam on the fuse element 13 to cut the same.

In accordance with the first embodiment, the fuse element 13 composed of Al alloy is formed in the Al alloy wiring layer in the uppermost layer (top metal). Therefore, a film of the interlayer dielectric film remaining on the fuse element does not have to be controlled by etching like a conventional semiconductor device, and the thickness of the dielectric film over the fuse element 13 can be controlled with the film thickness of the silicon oxide film 16. Accordingly, the film thickness of the dielectric film over the fuse element 13 can be readily controlled. As a result, cutting failures in the fuse cutting step can be reduced.

Also, in accordance with the first embodiment, in the etching step to form the opening section 18a over the pad 15, an unnecessary amount of over-etching does not need to be conducted like the conventional method for manufacturing semiconductor devices. Accordingly, this can prevent the surface of the pad 15 from being roughened.

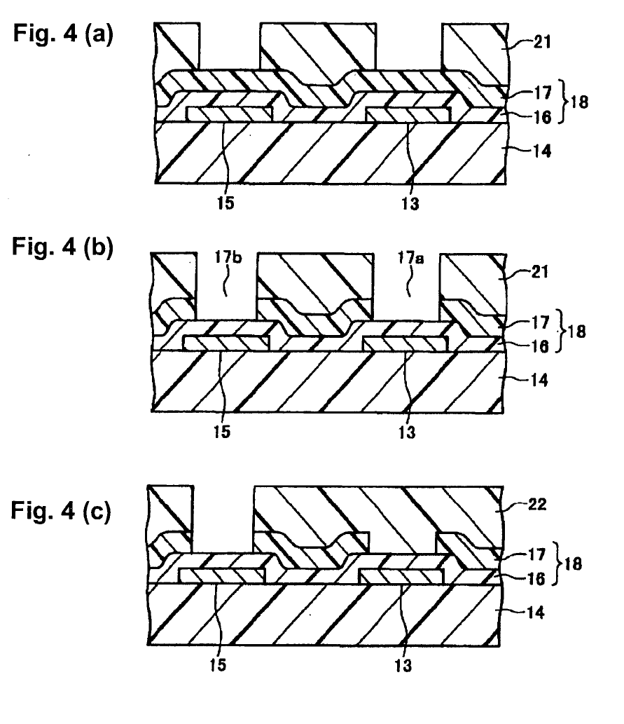

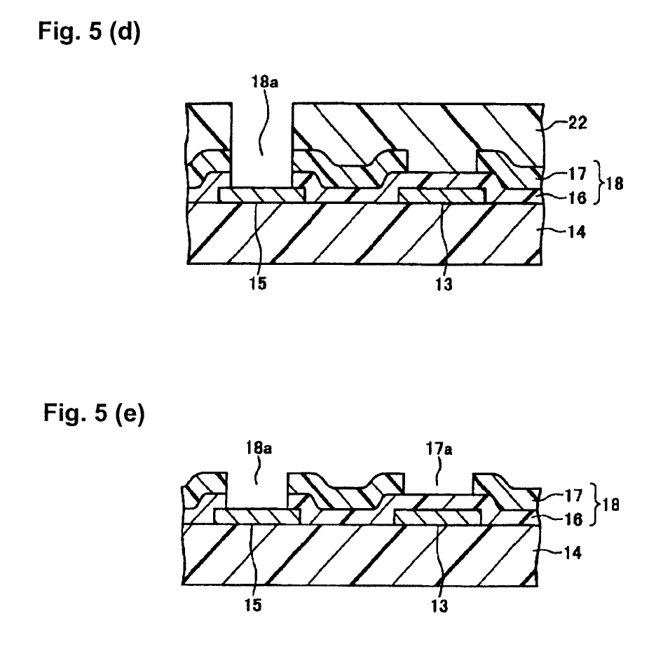

FIGS. 4(a)-(c) and FIGS. 5(d) and 5(e) show in cross section a method for manufacturing a semiconductor device equipped with a fuse element in accordance with a second embodiment of the present invention. The same portions as those shown in FIGS. 2 and 3 are indicated by the same reference numbers, and only different portions will be described.

As shown in FIG. 4(a), a photoresist film is coated on a passivation film 18, and the photoresist film is exposed and developed, whereby a resist pattern 21 is formed on the passivation film 18.

Then, as shown in FIG. 4(b), a silicon nitride film 17 is etched using the resist pattern 21 as a mask. As a result, an opening section 17b located above the pad 15 and a window for fusing 17a located above the fuse element 13 are formed in the silicon nitride film 17.

Next, as shown in FIG. 4(c), the resist pattern 21 is removed. Then, a photoresist film is coated on the passivation film 18, and the photoresist film is exposed and developed, whereby a resist pattern 22 is formed on the passivation film 18.

Then, as shown in FIG. 5(d), the silicon oxide film 16 is etched using the resist pattern 22 as a mask. As a result, an opening section 18a located above the pad 15 is formed in the passivation film 18, and the surface of the pad 15 is exposed through the opening section 18a. Then, as shown in FIG. 5(e), the resist pattern 22 is removed.

The second embodiment can provide effects similar to those of the first embodiment. More specifically, the thickness of the dielectric film over the fuse element 13 can be controlled with the film thickness of the silicon oxide film 16. Accordingly, the film thickness of the dielectric film over the fuse element 13 can be readily controlled. As a result, cutting failures in the fuse cutting step can be reduced. Also, the surface of the pad 15 can be prevented from being roughened.

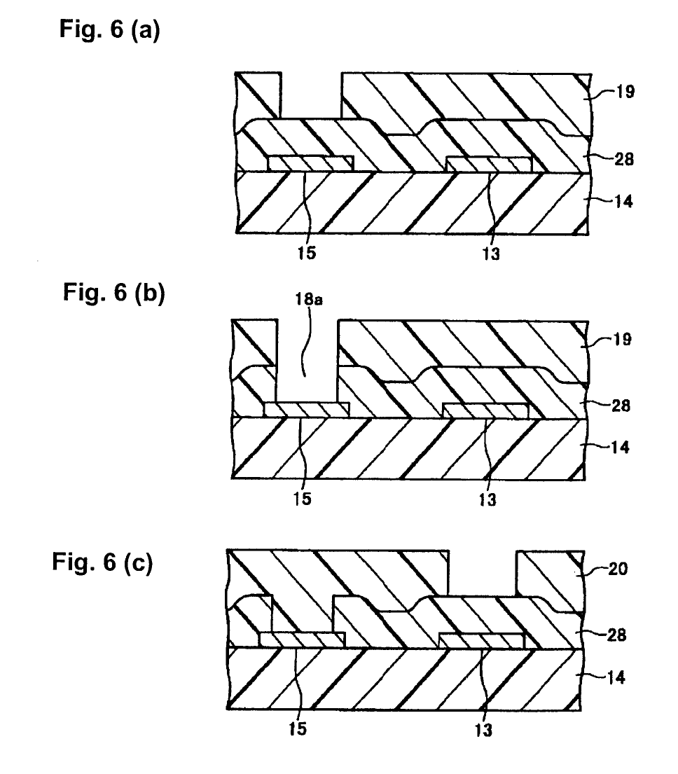

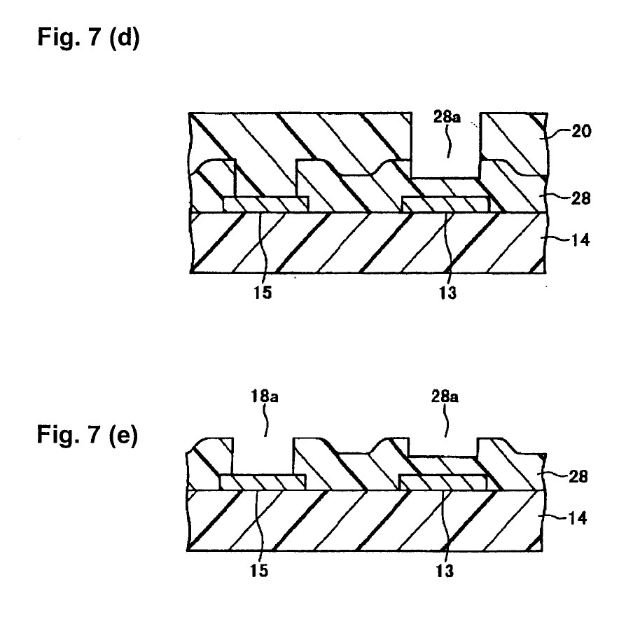

FIGS. 6(a)-(c) and FIGS. 7(d) and 7(e) show in cross section a method for manufacturing a semiconductor device equipped with a fuse element in accordance with a third embodiment of the present invention. The same portions as those shown in FIGS. 2 and 3 are indicated by the same reference numbers, and only different portions will be described.

As shown in FIG. 6(a), a passivation film 28 composed of a silicon nitride film or the like is deposited on the entire surface including a pad 15 and a fuse element 13 by a CVD method. Then, a photoresist film is coated on the passivation film 28, and the photoresist film is exposed and developed, whereby a resist pattern 19 is formed on the passivation film 28.

Next, as shown in FIG. 6(b), the passivation film 28 is etched using the resist pattern 19 as a mask. As a result, an opening section 18a located above the pad 15 is formed in the passivation film 28, and the surface of the pad 15 is exposed.

Next, as shown in FIG. 6(c), the resist pattern 19 is removed. Next, a photoresist film is coated on the passivation film 28, and the photoresist film is exposed and developed, whereby a resist pattern 20 is formed on the passivation film 28.

Next, as shown in FIG. 7(d), the passivation film 28 is subject to a half-etching using the resist pattern 20 as a mask. As a result, a window for fusing 28a located above the fuse element 13 is formed in the passivation film 28, and the passivation film 28 having a specified thickness is left on the fuse element 13. In this instance, the half-etching is controlled by the etching time. Next, as shown in FIG. 7(e), the resist pattern 20 is removed.

In accordance with the third embodiment, the fuse element 13 composed of Al alloy is formed in the Al alloy wiring layer in the uppermost layer (top metal). Therefore, a remaining film of the dielectric film that is to remain on the fuse element 13 is more readily controlled compared to a conventional semiconductor device. As a result, cutting failures in the fuse cutting step can be reduced.

Also, in accordance with the third embodiment, in the etching step to form the opening section 18a over the pad 15, an unnecessary amount of over-etching does not need to be conducted like the conventional method for manufacturing semiconductor devices. Accordingly, this can prevent the surface of the pad 15 from being roughened.

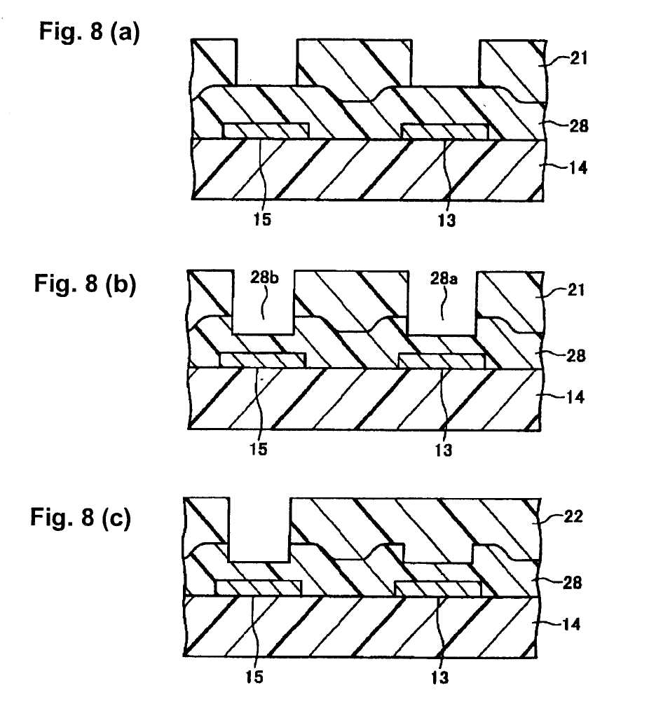

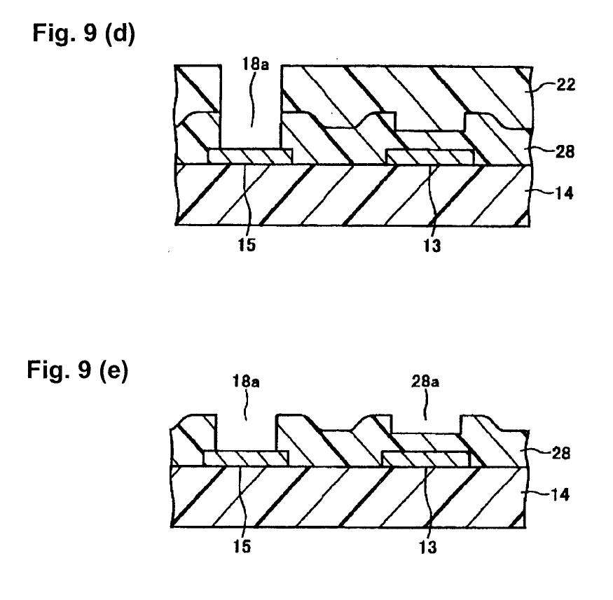

FIGS. 8(a)-(c) and FIGS. 9(d) and 9(e) show in cross section a method for manufacturing a semiconductor device equipped with a fuse element in accordance with a fourth embodiment of the present invention. The same portions as those shown in FIGS. 6 and 7 are indicated by the same reference numbers, and only different portions will be described.

As shown in FIG. 8(a), a photoresist film is coated on a passivation film 28, and the photoresist film is exposed and developed, whereby a resist pattern 21 is formed on the passivation film 28.

Next, as shown in FIG. 8(b), the passivation film 28 is subject to a half-etching using the resist pattern 21 as a mask. As a result, an opening section 28b located above a pad 15 and an opening section 28a located above a fuse element 13 are formed in the passivation film 28, and the passivation film 28 having a specified thickness is left on the fuse element 13. In this instance, the half-etching is controlled by the etching time.

Next, as shown in FIG. 8(c), the resist pattern 21 is removed. Then, a photoresist film is coated on a passivation film 28, and the photoresist film is exposed and developed, whereby a resist pattern 22 is formed on the passivation film 28.

Then, as shown in FIG. 9(d), the passivation film 28 is etched using the resist pattern 22 as a mask. As a result, an opening section 18a located above a pad 15 is formed in the passivation film 28, and the surface of the pad 15 is exposed. Then, as shown in FIG. 9(e), the resist pattern 22 is removed.

The fourth embodiment can provide effects similar to those of the third embodiment.

It is noted that the present invention is not limited to the embodiments described above, and many modifications can be made and implemented. For example, in the first and second embodiments described above, the silicon oxide film 16 and the silicon nitride film 17 are formed by a CVD method. However, the silicon oxide film 16 and the silicon nitride film 17 can be formed by a high-density plasma CVD method.

Also, in the first and second embodiments, the silicon oxide film 16 is formed on the fuse element 13 and the pad 15, and the silicon nitride film 17 is formed on the silicon oxide film. However, a first silicon oxide film may be formed on the fuse element 13 and the pad 15, a second silicon oxide film may be formed on the first silicon oxide film by a high-density plasma CVD method, and a silicon nitride film can be formed on the second silicon oxide film.

Also, in the third and fourth embodiments, the passivation film 28 is formed by a CVD method. However, the passivation film 28 can be formed by a high-density plasma CVD method.

Also, in the third and fourth embodiments, the passivation film 28 is formed with a silicon nitride film. However, the passivation film 28 can be formed with a silicon oxide film.

As described above, in accordance with the present invention, fuse elements and the uppermost wiring layer are formed in the same layer. Accordingly, fuse elements, semiconductor devices and methods for manufacturing the same, which reduce failures in cutting fuse elements are provided.

The entire disclosure of Japanese Patent Application No. 2001-255995 filed Aug. 27, 2001 is incorporated by reference.

What is claimed is:

1. A device comprising:
a dielectric film; and
a fuse element formed on the dielectric film;
wherein the fuse element and an uppermost wiring layer are formed in the same layer.

2. A fuse element according to claim 1, wherein the fuse element and pads for external connection are formed in the same layer.

3. A fuse element according to claim 1, wherein the wiring layer further comprises an Al alloy film.

4. A semiconductor device comprising:
a fuse element formed on a dielectric film, the fuse element and an uppermost wiring layer being formed in the same layer;
a first passivation film formed on the fuse element and the dielectric film;
a second passivation film formed on the first passivation film; and
a window for fusing formed in the second passivation film, and located above the fuse element.

5. A semiconductor device comprising:
a pad formed on a dielectric film;
a fuse element formed on the dielectric film, the fuse element and the pad being formed in the same layer;
a first passivation film formed on the fuse element, the pad and the dielectric film;
a second passivation film formed on the first passivation film;
a window for fusing formed in the second passivation film, and located above the fuse element; and
an opening section formed in the first passivation film and the second passivation film, and located above the pad.

6. A semiconductor device comprising:
a fuse element formed on a dielectric film, the fuse element and an uppermost wiring layer being formed in the same layer;
a passivation film formed on the fuse element and the dielectric film; and
a window for fusing formed in the passivation film, and located above the fuse element, wherein part of the passivation film remains between the fuse element and the window for fusing.

7. A semiconductor device comprising:
a pad formed on a dielectric film;
a fuse element formed on the dielectric film, the fuse element and the pad being formed in the same layer;
a passivation film formed on the pad and the dielectric film;
a window for fusing formed in the passivation film, and located above the fuse element; and
an opening section formed in the passivation film, and located above the pad, wherein part of the passivation film remains between the fuse element and the window for fusing, and the pad is exposed through the opening section.

8. A semiconductor device according to claim 7, further comprising a first wiring formed below the dielectric film and connected to one end of the fuse element, and a second wiring formed below the dielectric film and connected to another end of the fuse element.

9. A method for manufacturing a semiconductor device, the method comprising the steps of:
depositing a metal film on a dielectric film, and pattering the metal film to form a fuse element on the dielectric film;
forming a first passivation film on the fuse element and the dielectric film;
forming a second passivation film on the first passivation film; and
forming a window for fusing located above the fuse element in the second passivation film, wherein the fuse element and an uppermost wiring layer are formed in the same layer.

10. A method for manufacturing a semiconductor device, the method comprising the steps of:
depositing a metal film on a dielectric film, and pattering the metal film to form a fuse element and a pad on the dielectric film;
forming a first passivation film on the fuse element, the pad and the dielectric film;
forming a second passivation film on the first passivation film;
etching the first passivation film and the second passivation film to form an opening section located above the pad in the first passivation film and the second passivation film; and
etching the second passivation film to form a window for fusing located above the fuse element in the second passivation film.

11. A method for manufacturing a semiconductor device, the method comprising the steps of:
depositing a metal film on a dielectric film, and pattering the metal film to form a fuse element and a pad on the dielectric film;
forming a first passivation film on the fuse element, the pad and the dielectric film;
forming a second passivation film on the first passivation film;
etching the first passivation film to form a window for fusing located above the fuse element in the first passivation film, and forming a first opening section located above the pad in the first passivation film; and
etching the second passivation film to form a second opening section located above the pad in the second passivation film,
wherein the first opening section is continuous with the second opening section.

12. A method for manufacturing a semiconductor device, the method comprising the steps of:
depositing a metal film on a dielectric film, and pattering the metal film to form a fuse element on the dielectric film;
forming a passivation film on the fuse element and the dielectric film; and
forming a window for fusing located above the fuse element in the passivation film, wherein the fuse element and an uppermost wiring layer are formed in the same layer, and part of the passivation film remains between the fuse element and the window for fusing.

13. A method for manufacturing a semiconductor device, the method comprising the steps of:
depositing a metal film on a dielectric film, and pattering the metal film to form a fuse element and a pad on the dielectric film;
forming a passivation film on the fuse element, the pad and the dielectric film; and
etching the passivation film to form an opening section located above the pad in the passivation film; and
etching the passivation film to form a window for fusing located above the fuse element,
wherein part of the passivation film remains between the fuse element and the window for fusing.

14. A method for manufacturing a semiconductor device according to claim 13, further comprising the step of cutting the fuse element after the step of forming the window for fusing.

15. A method for manufacturing a semiconductor device, the method comprising the steps of:
depositing a metal film on a dielectric film, and pattering the metal film to form a fuse element and a pad on the dielectric film;
forming a passivation film on the fuse element, the pad and the dielectric film;
etching the passivation film to form a window for fusing located above the fuse element in the passivation film, and forming a first opening section located above the pad in the passivation film; and
etching the passivation film to form a second opening section located above the pad,
wherein part of the passivation film remains between the fuse element and the window for fusing, and the first opening section is continuous with the second opening section.

16. A method for manufacturing a semiconductor device according to claim 15, further comprising the step of cutting the fuse element after the step of forming the second opening section.
